(19) United States
(12) Patent Application Publication
(10) Pub. No.: US 2002/0141842 A1
(43) Pub. Date: Oct. 3, 2002

(54) Twist drill

(76) Inventors: Hideo Tsuzaka, Yokohama-shi (JP); Yoshifumi Koike, Yokohama-shi (JP); Kiichiro Kura, Yokohama-shi (JP); Kazuto Nakada, Nagano-ken (JP)

Correspondence Address: Kit M. Stetina, STETINA BRUNDA GARRED & BRUCKER, Suite 250, 75 Enterprise, Aliso Viejo, CA, 92656, US

(21) Appl. No.: 09/990,757

(22) Filed: Nov. 14, 2001

(30) Foreign Application Priority Data
Nov. 16, 2000 (JP) 2000-349480

(51) Int. Cl. B23B 51/02

(52) U.S. Cl. 408/230; 408/226

(57) ABSTRACT

A twist drill is made of a carbide alloy and has a pair of helical flutes. The flutes are defined by heel surfaces. Each heel surface bulges, or is formed arcuate, and contacts a margin. The center of the arc is located in the drill. The radius of curvature of each heel surface is from one sixth to one third of the diameter of a drill portion. Stress that acts on heels due to forming holes is dispersed by the arcuate shape. This improves the rigidity of the twist drill. Also, swarf is reliably cleared and is not stuck in the flutes. This improves the smoothness of the surface of the formed hole.

### BACKGROUND OF THE INVENTION

The present invention relates to a carbide alloy twist drill that is used for making holes.

FIGS. 9 and 10 illustrate a prior art carbide alloy twist drill. The twist drill of FIGS. 9 and 10 has a shank and a drill portion, and is attached to a machine tool at the shank. The twist drill also has two helical flutes 26. Part of each flute 26 is formed by a heel surface 25. In a cross-sectional view that is perpendicular to the axis of the drill, each heel surface 25 is concaved. Swarf produced by cutting edges 28 is cleared from a formed hole through the flutes 26.

However, since the web thickness of the drill portion is small, the rigidity, such as bending strength and the torsional strength, of the twist drill is relatively low. To improve the rigidity, the web thickness is increased in prior art drills. However, this reduces the cross-sectional area of each helical flute for clearing swarf, and thus degrades the performance of swarf clearing. As a result, the surface of a formed hole becomes rough. If the web thickness is reduced for enlarging the cross-sectional area of each helical flute, the drill portion may be bent or buckled by cutting force, which increases as the thickness of a cut material increases. This may displaces a formed hole from a desired position. Therefore, the thickness of material to be machined is limited. In this manner, if the cross-sectional areas of helical flutes are increased, the rigidity of the drill portion is lowered despite the improvement of swarf clearing performance. If the cross-sectional areas of the helical flutes are reduced, the swarf clearing performance is lowered despite the improvement of the rigidity of the drill portion. That is, the smoothness of the wall of a formed hole and the rigidity of a twist drill against bending are contradictory. Therefore, improving the smoothness of the surface of a formed hole is not compatible with improving the rigidity of the drill against bending. In other words, it is difficult to improve the swarf clearing performance and the rigidity of a twist drill at the same time.

### SUMMARY OF THE INVENTION

Accordingly, it is an object of the present invention to provide a twist drill that has sufficient cross-sectional area for helical flutes for clearing swarf and is sufficiently rigid.

To achieve the foregoing and other objectives and in accordance with the purpose of the present invention, a twist drill having drill portion and a heel surface is provided. The heel surface is formed in the drill portion. The heel surface defines a flute and has a bulging arcuate cross section. The radius of curvature of the heel surface is between one sixth and one third of the diameter of the drill portion.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a front view illustrating a twist drill according to one embodiment of the present invention;

FIG. 2 is a side view illustrating the twist drill of FIG. 1;

FIG. 3 is a partial side view illustrating the distal end of the twist drill shown in FIG. 2;

FIG. 4 is a partial perspective view illustrating the twist drill shown in FIG. 1;

FIG. 5 is diagram showing the twist drill shown in FIG. 1 when the twist angle is less than thirty-five degrees;

FIG. 6 is a partial perspective view illustrating the twist drill shown in FIG. 5;

FIG. 7 is a graph showing the result of machining by the twist drill shown in FIG. 1;

FIG. 8 is a graph showing the result of machining by a prior art twist drill shown in FIGS. 9 and 10;

FIG. 9 is a front view illustrating a prior art twist drill; and

FIG. 10 is a side view illustrating the twist drill shown if FIG. 9.

### DETAILED DESCRIPTION OF THE PREFERRED EMBODIMENTS

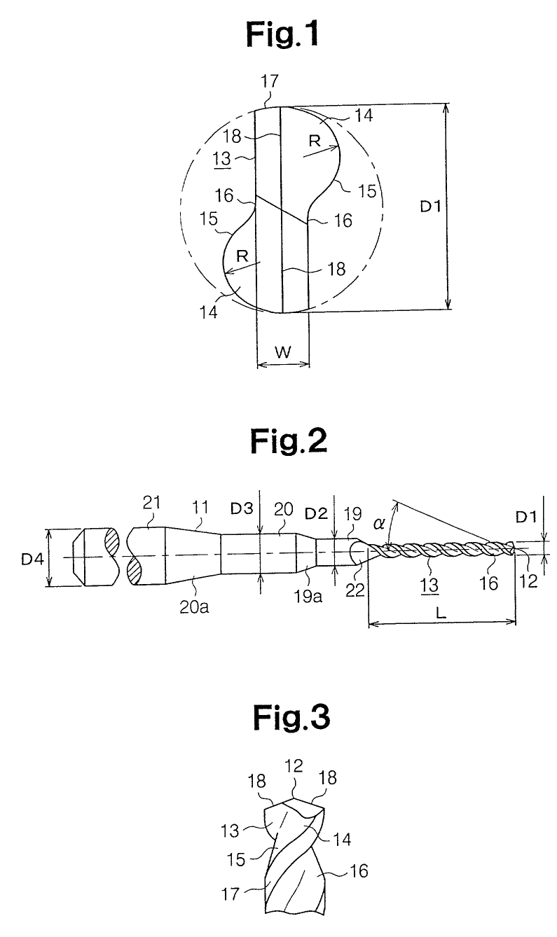

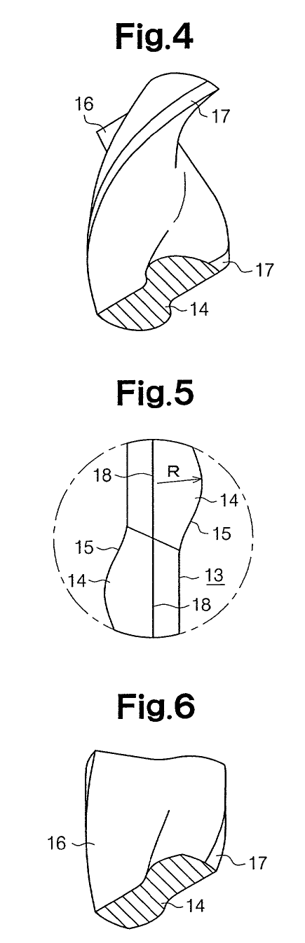

A twist drill 11 according to the present invention will now be described with reference to FIGS. 1 to 7.

FIGS. 1 to 4 illustrate the twist drill 11, which is made of a carbide alloy. The twist drill 11 is used for making holes in a printed wiring board and a plastic glass fiber copper clad laminate used for semiconductor packages. The twist drill 11 is dry type and requires no cutting oil. The twist drill 11 includes a shank 21, which is located at the proximal end, and a drill portion 13, which is located at the distal portion. The diameter D1 of the drill portion 13 is between 0.1 mm to 0.5 mm. More preferably, the diameter D1 is between 0.1 mm to 0.4 mm. The diameter of the shank 21 is 3.175 mm.

The drill portion 13 has two helical flutes 16, which are wound clockwise as viewed from the distal end 12. As shown in FIG. 1, each helical flute 16 includes a flat surface and a heel surface 15, which is arcuately protruded. Part of the drill portion 13 that corresponds to each heel surface 15, or a heel portion 14, has a substantially semicircular cross section. Since the number of the helical flutes 16 is two, a pair of cutting edges 18 are formed in the distal end of the drill portion 13. The two helical flutes 16 have the same cross section and are symmetric with respect to the axis the drill 11. Each heel surface 15 contacts a margin 17. The center of the arc of each heel surface 15 is located in the drill 11. The radius of curvature R of each heel surface 15 is between one sixth and one third of the diameter D1 of the drill portion 13. The radius of curvature R is determined by the angle of torsion α of the helical flutes 16.

When forming a hole, the twist drill 11 is rotated counterclockwise as viewed from the distal end 12. The cutting edges 18 cut a work and swarf is cleared from the formed hole through the helical flutes 16. At this time, since the heel surfaces 15 are arcuate, stress due to forming the hole is dispersed and does not acts on the drill portion 13 in a concentrated manner. This improves the bending strength and the torsional strength of the twist drill 11 and thus improves the positioning accuracy of the distal end 12 during machining. Further, a relatively great cross-sectional area is used for clearing swarf created during machining, which prevents swarf from being stuck and improves the smoothness of the wall of the formed hole.

The thickness of the drill portion 13 is between 25% and 60% of the diameter D1. If the ratio is less than 25%, the drill portion 13 will be weak. If the ratio is greater than 60%, the cross-sectional area of the helical flutes 16 is too small and swarf will be stuck. Stuck swarf roughens the surface of the formed hole.

The angle of torsion α of the helical flutes 16 is set between 35° and 45°. More preferably, the angle of torsion α is set between 38° and 43°. If the angle α is less than 35°, the radius of curvature R of each heel surface 15 is too large as shown in FIGS. 5 and 6 and the thickness of the heel portion 14 is too small, which lowers the rigidity of the drill portion 13. If the angle α is greater than 45°, the cross-sectional area of the helical flutes 16 is too small and the swarf clearing performance is degraded.

The axial length L of the drill portion 13 is fifteen to thirty times longer than the diameter D1. If the drill length L is less than a length that is fifteen times as the diameter D1, the depth of formed holes is too small and thus is not practical. If the drill length L is greater than a length that is thirty times as the diameter D1, the aspect ratio of the diameter D1 and the length L is too great, which lowers the rigidity of the drill portion 13.

A transition part is located between the drill portion 13 and the shank 21. The transition part includes a small diameter portion 19 and a large diameter portion 20. The diameter D2 of the small diameter portion 19 is 20% to 50% greater than the diameter D1 of the drill portion 13. The diameter D3 of the large diameter portion 20 is between the diameter D2 and the diameter D4 of the shank 21. Tapered portions 19a, 20 are formed between the small diameter portion 19 and the large diameter portion 20, and between the large diameter portion 20 and the shank, respectively. The diameter of the twist drill 11 is gradually increases in the order of the diameter D1 of the drill portion 13, the diameter D2 of the small diameter portion D2, the diameter D3 of the large diameter portion D3, and the diameter D4 of the shank 21. This structure disperses stress and improves the rigidity of the drill 11. Step grooves 22 are formed in the small diameter portion 19. The step grooves 22 are continuously formed with the helical flutes 16. The step grooves 22 disperse stress due to hole forming and thus improves the strength of the small diameter portion 19.

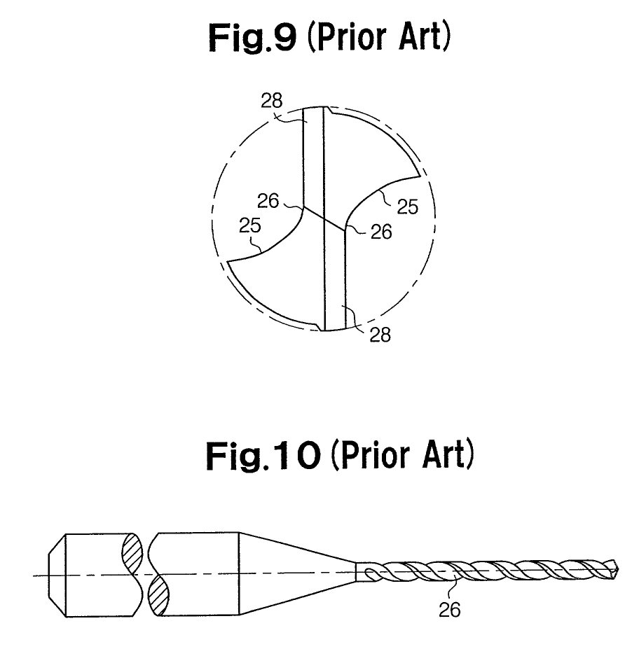

An experiment was performed by using the twist drill 11 and a prior art twist drill, which is shown in FIGS. 9 and 10. In the experiment, a large number of holes were formed by using the prior art twist drill and the drill 11, and the position of the lowest points of the holes were measured. The lowest point of each hole was measured relative to the axis of the spindle of a machine tool to which the twist drills were attached. In other words, the target location of each hole was defined as a point of origin, and the deviation of the actual lowest point from the point of origin was measured. The work used in the experiment was a sheet of layered materials, which includes a 0.2 mm aluminum thin plate, four 0.90 mm plastic glass cloth copper clad laminates, a 1.5 mm paper-phenol plate. The holes were formed from the side of the aluminum thin plate. The machining conditions of the drills were as follows:

the diameter D1 of the drill portion 13: 0.3 mm

the length L of the drill portion 13: 5.5 mm;

the rotational speed: 120,000 rpm; and

feed rate: 3 m/minute.

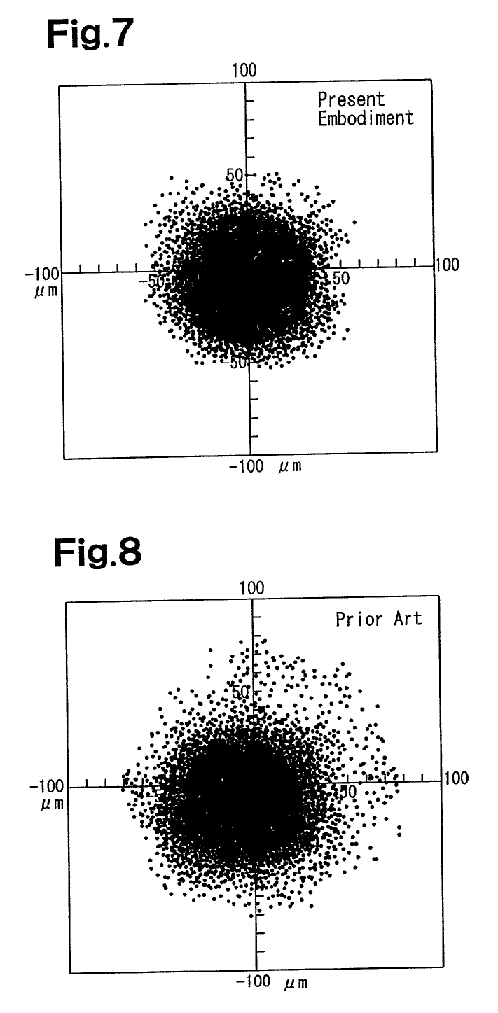

The results of the experiment are shown in FIGS. 7 and 8. These figures show the variations of the center of each formed hole relative to the axis of the spindle. Compared to the prior art, the variations of the lowest point of the holes are reduced in the illustrated embodiment. To analyze the variation degree of the lowest points of the formed holes, the sum of the average distance from the axis of the spindle to the lowest point of each hole (hereinafter referred to as average distance from the center) and the tripled standard deviation is used for evaluation. The sum will herein after be referred to as a variation value. The standard deviation refers to a statically calculated variation of the lowest points of the holes. The average distance from the center, the variation value, and the maximum roughness of the formed holes in the embodiment of FIG. 7 and in the prior art of in FIG. 8 are shown in the chart 1.

CHART 1

| | Average | | Maximum |
|---|---|---|---|
| | Distance from | | Roughness of the |
| | the Center | Variation value | Formed Holes |
| | (μm) | (μm) | (μm) |
| PRESENT | 18.5 | 51.8 | 4.5 |
| EMBODIMENT | | | |
| PRIOR ART | 24.9 | 65.3 | 9.0 |

As shown in chart 1, the variation value of the present embodiment is smaller than that of the prior art. This shows that the variation degree of the lowest points of the holes that were formed by the twist drill 11 of the illustrated embodiment is smaller than that of the prior art, thus, that the rigidity of the twist drill 11 is improved. The maximum roughness of the formed holes is smaller in the present embodiment than in the prior art. This shows that the present embodiment has an improved swarf clearing performance.

The twist drill 11 of the above illustrated embodiment has the following advantages.

(1) Each heel surface 15 is arcuate and the radius of curvature R is between one sixth and one third of the diameter D1 of the drill portion 13. This structure disperses the stress due to forming holes and improves the bending and torsional strength of the twist drill 11. The structure also guarantees the cross-sectional area of the helical flutes 16, which creates smooth flow of swarf.

(2) Since the twist drill 11 is made of carbide alloy, the drill 11 has a high rigidity and a high wear resistance.

(3) Since the twist drill 11 has an improved rigidity, the twist drill 11 is suitable for forming minute holes in materials that have great cutting resistance and tend to buckle, such as a printed wiring board, a plastic glass fiber copper clad laminate used for semiconductor packages.

(4) Since the torsional angle α is between 35° and 45°, the radius of curvature R of the heel portions 14, which is determined by the torsional angle α, is set in a range for improving the rigidity of the twist drill 11.

(5) Since the thickness W is between 25% and 60% of the diameter D1 of the drill portion 13, the rigidity of the twist drill 11 and the swarf clearing performance are improved.

(6) The length L of the drill portion 13 is in a range from fifteen times of the diameter D1 and the thirty times of the diameter D1. Therefore, the rigidity of the drill portion 13 is improved while maintaining the length L of the drill portion 13 practical.

(7) Since the drill 11 has the small diameter portion 19 and the large diameter portion 20, the diameter of the drill 11 gradually changes from the diameter D1 of the drill portion 13 to the diameter D4 of the shank, which improves the rigidity of the drill 11.

(8) The step grooves 22 smoothen the shapes of the upper ends of the helical flutes 16. This structure disperses stress and thus improves the strength of the small diameter portion 19.

It should be apparent to those skilled in the art that the present invention may be embodied in many other specific forms without departing from the spirit or scope of the invention. Particularly, it should be understood that the invention may be embodied in the following forms.

The number of the helical flutes 16 may be three or four, and the number of the cutting edges may be three or four.

The helical flute 16 may be wound counterclockwise as viewed from the distal end 12.

Therefore, the present examples and embodiments are to be considered as illustrative and not restrictive and the invention is not to be limited to the details given herein, but may be modified within the scope and equivalence of the appended claims.

What is claimed is:

1. A twist drill having drill portion and a heel surface, which is formed in the drill portion, wherein the heel surface defines a flute and has a bulging arcuate cross section, wherein the radius of curvature of the heel surface is between one sixth and one third of the diameter of the drill portion.

2. The twist drill according to claim 1, wherein the center of the arc of the heel surface is located in the drill portion.

3. The twist drill according to claim 1, wherein the drill is made of a carbide alloy.

4. The twist drill according to claim 1, wherein the diameter of the drill portion is between 0.1 mm and 0.4 mm.

5. The twist drill according to claim 1, wherein the angle of torsion of the flute is between 38° and 43°.

6. The twist drill according to claim 1, wherein the angle of torsion of the flute is between 35° and 45°.

7. The twist drill according to claim 1, wherein the thickness of the drill portion is between 25% and 60% of the diameter of the drill portion.

8. The twist drill according to claim 1, wherein the axial length of the drill portion is between fifteen to thirty times longer than the diameter of the drill portion.

9. The twist drill according to claim 1, further including a shank, the diameter of which is greater than that of the drill portion, wherein a transition part is located between the drill portion and the shank, the diameter of the transition part is smaller than that of the shank and is greater than that of the drill portion.

10. The twist drill according to claim 9, wherein the diameter of the transition part is 20% to 50% greater than that of the drill portion.

11. The twist drill according to claim 9, wherein the transition part includes a small diameter portion and a large diameter portion, wherein the small diameter portion is adjacent to the drill portion, and the large diameter portion is adjacent to the shank.

12. The twist drill according to claim 11, wherein the diameter of the small diameter portion is 20% to 50% greater than that of the drill portion.

13. The twist drill according to claim 9, wherein a step groove is formed in the transition part, and wherein the step groove is continuously formed with the flute.
